(19) United States
(12) Patent Application Publication
(10) Pub. No.: US 2025/0287784 A1
(43) Pub. Date: Sep. 11, 2025

(54) DISPLAY DEVICE

(71) Applicant: Samsung Display Co., LTD., Yongin-si (KR)

(72) Inventor: Hyoeng Ki KIM, Yongin-si (KR)

(21) Appl. No.: 18/930,474

(22) Filed: Oct. 29, 2024

(30) Foreign Application Priority Data
Mar. 11, 2024 (KR) 10-2024-0033831

(51) Int. Cl. H10K 59/122; H10K 59/38; H10K 59/80

(52) U.S. Cl. CPC H10K 59/122; H10K 59/38; H10K 59/873

(57) ABSTRACT

A display device includes: a substrate; a thin film transistor on the substrate; a protective layer on the thin film transistor; a bank layer on the protective layer and having a plurality of recesses; a plurality of light emitting elements including a pixel electrode, a light emitting layer, and a common electrode corresponding to each of the plurality of recesses on the bank layer; and a pixel definition layer defining a light emitting area on the bank layer, wherein the recess has a multi-stage slope, and the pixel electrode includes a first sloped portion having a first inclination along the multi-stage slope of the recess, and a second sloped portion above the first sloped portion and having a second inclination different from the first inclination, wherein a horizontal width of the first sloped portion is wider than a horizontal width of the second sloped portion.

### CROSS-REFERENCE TO RELATED APPLICATION

The present application claims priority to and the benefit of Korean Patent Application No. 10-2024-0033831, filed on Mar. 11, 2024, in the Korean Intellectual Property Office (KIPO), the entire disclosure of which is incorporated herein by reference.

### BACKGROUND

### 1. Field

Aspects of some embodiments of the present disclosure relate to a display device.

### 2. Description of the Related Art

As the information society develops, consumer demand for display devices for displaying images is increasing in various forms. For example, display devices may be applied to various electronic devices such as smartphones, digital cameras, laptop computers, navigation systems, and smart televisions.

A display device may be a flat panel display device such as a liquid crystal display device, a field emission display device, a light emitting display device, and the like. Light emitting display devices include, for example, an organic light emitting display device including an organic light emitting element, an inorganic light emitting display device including an inorganic light emitting element such as an inorganic semiconductor, and an ultra-compact light emitting display device including an ultra-compact light emitting element.

An organic light emitting element may include two opposing electrodes and a light emitting layer interposed between them. The light emitting layer may receive electrons and holes from two electrodes and recombine to generate excitons, and the generated excitons may change from an excited state to a ground state and emit light.

Unlike liquid crystal display devices, organic light emitting display device including organic light emitting elements generally do not require a separate light source as they use spontaneous light emitting elements to implement the display. Therefore, it is possible to be relatively thin and lightweight, and organic light emitting display devices may have relatively excellent characteristics such as a relatively high response speed, color reproduction rate, low power consumption, and a wide viewing angle.

However, as the viewing angle increases in an organic light emitting display device, the overall intensity of the display light may become relatively weaker, and the peak wavelength of each color may shift toward a shorter wavelength, resulting in color coordinate distortion.

The above information disclosed in this Background section is only for enhancement of understanding of the background and therefore the information discussed in this Background section does not necessarily constitute prior art.

### SUMMARY

Aspects of some embodiments of the present disclosure include a display device including a pixel electrode having a multi-stage inclined structure, which may reduce the luminance ratio deviation depending on the viewing angle while relatively improving the light emission efficiency from the front.

However, aspects of embodiments according to the present disclosure are not restricted to those specifically set forth herein. The above and other aspects of embodiments according to the present disclosure will become more apparent to one of ordinary skill in the art to which the disclosure pertains by referencing the detailed description of the disclosure given below.

According to some embodiments, a display device includes a a substrate, a thin film transistor on the substrate, a protective layer on the thin film transistor, a bank layer on the protective layer and having a plurality of recesses, a plurality of light emitting elements including a pixel electrode, a light emitting layer, and a common electrode corresponding to each of the plurality of recesses on the bank layer and a pixel definition layer defining a light emitting area on the bank layer, wherein the recess has a multi-stage slope, and the pixel electrode includes a first sloped portion having a first inclination along the multi-stage slope of the recess, and a second sloped portion above the first sloped portion and having a second inclination different from the first inclination, wherein a horizontal width of the first sloped portion is wider than a horizontal width of the second sloped portion.

According to some embodiments, the horizontal width of the first sloped portion is 3 μm to 5 μm, wherein the horizontal width of the second sloped portion is 1 μm to 3 μm.

According to some embodiments, the second inclination is smaller than the first inclination.

According to some embodiments, the first inclination is in the range of 20° to 30°, wherein the second inclination is in the range of 5° to 15°.

According to some embodiments, the pixel electrode further comprises a bottom portion connected to a bottom of the first sloped portion, and a top portion connected to a top of the second sloped portion and on a top surface of the bank layer.

According to some embodiments, the pixel definition layer partially overlaps the top portion.

According to some embodiments, the light emitting layer overlaps a bottom portion, a first sloped portion, and a second sloped portion of the pixel electrode.

According to some embodiments, the second inclination is greater than the first inclination.

According to some embodiments, the first inclination is in the range of 10° to 30°, wherein the second inclination is in the range of 30° to 60°.

According to some embodiments, the recess has a multi-stage inclined structure.

According to some embodiments, a display device includes a a substrate including a first light emitting area and a second light emitting area, a thin film transistor on the substrate, a protective layer on the thin film transistor, a bank layer on the protective layer and having a first recess and a second recess overlapping the first light emitting area and the second light emitting area, respectively, a first light emitting element including a first pixel electrode, a first light emitting layer, and a common electrode on the bank layer to correspond to the first recess, a second light emitting element including a second pixel electrode, a second light emitting layer, and a common electrode on the bank layer to correspond to the second recess and a pixel definition layer defining a light emitting area on the bank layer, herein the first pixel electrode has a single-layer inclined portion, wherein the second pixel electrode has a multi-layer inclined portion, and the multi-layered inclined portion includes a first sloped portion having a first inclination, and a second sloped portion above the first sloped portion and having a second inclination different from the first inclination, wherein a horizontal width of the first sloped portion is wider than a horizontal width of the second sloped portion.

According to some embodiments, the horizontal width of the first sloped portion is 3 μm to 5 μm, wherein the horizontal width of the second sloped portion is 1 μm to 3 μm.

According to some embodiments, the second inclination is smaller than the first inclination.

According to some embodiments, the first inclination is in the range of 20° to 30°, wherein the second inclination is in the range of 5° to 15°.

According to some embodiments, the first recess has a single-layer inclined structure, wherein the second recess has a multi-stage inclined structure.

According to some embodiments, the second inclination is greater than the first inclination.

According to some embodiments, the first inclination is in the range of 10° to 30°, wherein the second inclination is in the range of 30° to 60°.

According to some embodiments, the second light emitting layer overlaps a bottom portion, a first sloped portion, and a second sloped portion of the pixel electrode.

According to some embodiments, the display device further comprises thin film encapsulation layer on the first light emitting element and the second light emitting element, a color filter layer on the thin film encapsulation layer, an overcoat layer and a touch electrode layer between the thin film encapsulation layer and the color filter layer, wherein the thin film encapsulation layer includes a first inorganic film layer, a second inorganic film layer, and an organic film layer between the first inorganic film layer and the second inorganic film layer.

According to some embodiments, the color filter layer includes a first color filter overlapping the first light emitting area and a second color filter overlapping the second light emitting area, wherein the first color filter is either a blue color filter that transmits blue light or a red color filter that transmits red light, and the second color filter is a green color filter that transmits green light.

In a display device according to some embodiments, the white angular dependency (WAD) may be relatively improved, and front light efficiency may be relatively improved.

However, the characteristics of embodiments according to the present disclosure are not limited to the aforementioned characteristics, and various other characteristics are included in the specification.

### BRIEF DESCRIPTION OF THE DRAWINGS

The above and other aspects and features of embodiments according to the present disclosure will become more apparent by describing in more detail aspects of some embodiments thereof with reference to the attached drawings, in which:

FIG. 1 is a schematic perspective view of an electronic device according to some embodiments.

FIG. 2 is a perspective view illustrating a folding state of a foldable display device according to some embodiments.

FIG. 3 is a perspective view illustrating an unfolding state of the foldable display device of FIG. 2.

FIG. 4 is a perspective view illustrating a display device included in an electronic device according to some embodiments.

FIG. 5 is a cross-sectional view illustrating an example of a display panel cut along X1-X1′ of FIG. 4.

FIGS. 6 to 10 are plan views illustrating pixels PX according to some embodiments.

FIG. 11 is a cross-sectional view illustrating a display device according to some embodiments.

FIG. 12 is a graph to illustrate the correlation between the horizontal width of the inclined portion, the luminance ratio deviation dLvA, and the frontal contrast luminance in the display device according to some embodiments as illustrated in FIG. 11.

FIG. 13 is a graph to illustrate the correlation between the slope of the slope, the luminance ratio deviation dLvA, and the frontal contrast luminance in the display device according to some embodiments as illustrated in FIG. 11.

FIG. 14 is a cross-sectional view illustrating a display device according to some embodiments.

FIG. 15 is an enlarged view to illustrate the multi-stage inclined structure of the pixel electrodes of FIG. 14.

FIG. 16 is a cross-sectional view illustrating a display device according to some embodimentst.

FIG. 17 is an enlarged view to illustrate the multi-stage inclined structure of the pixel electrode of FIG. 12.

FIG. 18 is a graph illustrating a luminance ratio deviation of a display device employing a multi-stage inclined structure according to some embodiments as described with reference to FIGS. 16 and 17.

FIG. 19 is a graph illustrating frontal contrast luminance of a display device employing the multi-stage inclined structure described with reference to FIGS. 16 and 17.

FIG. 20 is a cross-sectional view illustrating a display device including a light emitting area emitting light of different wavelengths, according to some embodiments.

FIG. 21 is a cross-sectional view illustrating a display device including a light emitting area emitting different wavelengths of light according to some embodiments.

### DETAILED DESCRIPTION

Aspects of some embodiments will now be described more fully hereinafter with reference to the accompanying drawings. The embodiments may, however, be provided in different forms and should not be construed as limiting. The same reference numbers and/or reference characters indicate the same components throughout the disclosure. In the accompanying figures, the thickness of layers and regions may be exaggerated for clarity.

Some of the parts which are not associated with the description may not be provided in order to describe embodiments of the disclosure.

It will also be understood that when a layer is referred to as being “on” another layer or substrate, it can be directly on the other layer or substrate, or intervening layers may also be present. In contrast, when an element is referred to as being “directly on” another element, there may be no intervening elements present.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

The spatially relative terms “below,” “beneath,” “lower,” “above,” “upper,” or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

When an element is referred to as being “connected” or “coupled” to another element, the element may be “directly connected” or “directly coupled” to another element, or “electrically connected” or “electrically coupled” to another element with one or more intervening elements interposed therebetween. It will be further understood that when the terms “comprises,” “comprising,” “has,” “have,” “having,” “includes” and/or “including” are used, they may specify the presence of stated features, integers, steps, operations, elements and/or components, but do not preclude the presence or addition of other features, integers, steps, operations, elements, components, and/or any combination thereof.

It will be understood that, although the terms “first,” “second,” “third,” or the like may be used herein to describe various elements, these elements should not be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the teachings herein.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within ±30%, 20%, 10%, 5% of the stated value.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” For the purposes of this disclosure, the phrase “at least one of A or B” may be construed as A only, B only, or any combination of A and B. Also, “at least one of X, Y, or Z” and “at least one selected from the group consisting of X, Y, and Z” may be construed as X only, Y only, Z only, or any combination of two or more of X, Y, and Z.

Unless otherwise defined or implied herein, all terms used herein (including technical and scientific terms) have the same meaning as commonly understood by those skilled in the art to which this disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

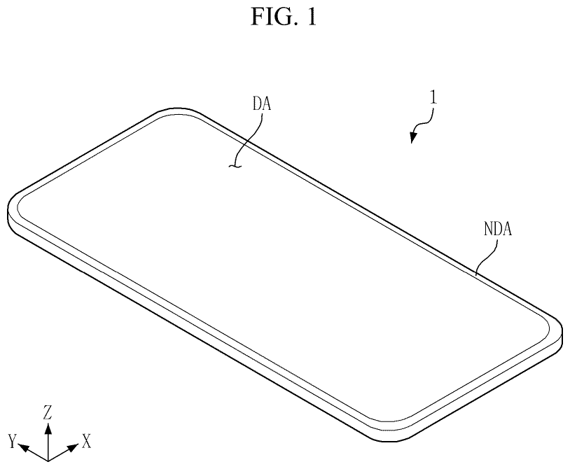

FIG. 1 is a schematic perspective view of an electronic device according to some embodiments.

Referring to FIG. 1, the electronic device 1 displays moving images (e.g., video images) or still images (e.g., static images). The electronic device 1 may refer to any electronic device that includes a display screen. For example, the electronic device 1 may include a television, laptop, monitor, billboard, Internet of Things, mobile phone, smartphone, tablet personal computer (PC), electronic watch, smartwatch, watch phone, head-mounted display, mobile communication terminal, electronic notebook, e-book, portable multimedia player (PMP), navigation, gaming device, digital camera, camcorder, etc. that provides a display screen.

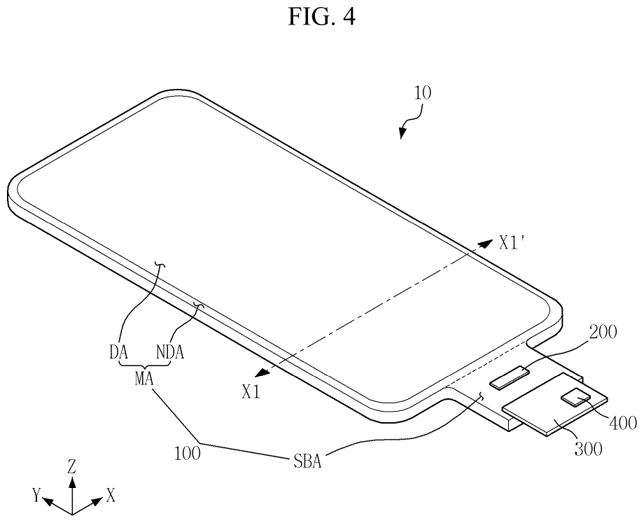

The electronic device 1 may include a display device (‘10’ in FIG. 4) that provides a display screen. Examples of display devices include an inorganic light emitting diode display, an organic light emitting display device, a quantum dot light emitting display device, a plasma display device, a field emission display device, and the like. Hereinafter, an organic light emitting diode display device is used as an example of a display device, but it is not limited thereto, and the same technical concept may be applied to other display devices as long as it is applicable.

The shape of the electronic device 1 may be modified in various ways. For example, the electronic device 1 may have a shape such as a horizontally long rectangle, a vertically long rectangle, a square, a square with rounded corners (vertices), other polygons, a circle, an ellipse, or the like, in a plan view (e.g., a view toward a display surface of the electronic device 1). The shape of the display area DA of the electronic device 1 may also be the same as, or similar to, the overall shape of the electronic device 1. In FIG. 1, the electronic device 1 having a long rectangular shape in the second direction DR2 is illustrated.

The electronic device 1 may include a display area DA and a non-display area NDA. The display area DA is an area where images may be displayed, and the non-display area NDA is an area where images are not displayed. The display area DA may be referred to as an active area, and the non-display area NDA may be referred to as an inactive area. The display area DA may generally occupy the center of the electronic device 1, and the non-display area NDA may surround (e.g., in a periphery or outside a footprint of) the display area DA.

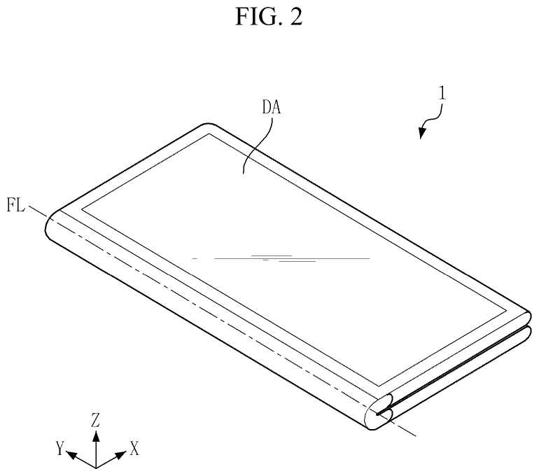

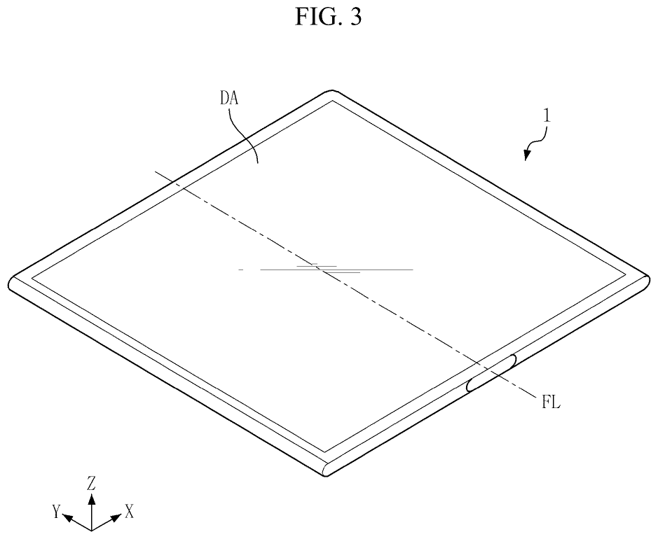

FIG. 2 is a perspective view illustrating a folding state of a foldable display device according to some embodiments. FIG. 3 is a perspective view illustrating an unfolding state of the foldable display device of FIG. 2.

Referring to FIGS. 2 and 3, the electronic device 1 according to some embodiments may be a foldable display device. The foldable electronic device 1 may be folded around the folding axis FL. The display area DA may be located outside and/or inside the foldable electronic device 1. According to some embodiments, the foldable electronic device 1 of FIGS. 2 and 3 illustrates that the display area DA is located on the outer and inner sides, respectively.

The display area DA may be located outside the electronic device 1. The outer surface of the folded electronic device 1 may include the display area DA, and the inner surface of the unfolded electronic device 1 may include the display area DA.

FIG. 4 is a perspective view illustrating a display device included in an electronic device according to some embodiments.

Referring to FIG. 4, an electronic device 1 according to some embodiments may include a display device 10. The display device 10 may include a screen for displaying images on the electronic device 1. The display device 10 may have a planar shape similar to that of the electronic device 1. For example, the display device 10 may have a shape similar to a rectangle having a short side in the first direction X and a long side in the second direction Y. The corner where the short side in the first direction X and the long side in the second direction Y meet may be rounded to have a curvature but is not limited to this and may also be formed at a right angle. The planar shape of the display device 10 is not limited to a square, and may be similar to other polygons, circles, or ovals.

The display device 10 may include a display panel 100, a display driver 200, a circuit board 300, and a touch driver 400.

The display panel 100 may include a main area MA and a sub-area SBA.

The main area MA may include a display area DA including pixels that display an image, and a non-display area NDA arranged around (e.g., in a periphery or outside a footprint of) the display area DA. The display area DA may emit light from a plurality of light emitting areas or a plurality of opening areas, which will be described in more detail later. For example, the display panel 100 may include a pixel circuit including switching elements, a pixel definition layer defining a light emitting area or an opening area, and a self-light emitting element.

For example, the self light emitting element may include at least one of an organic light emitting diode (Organic Light Emitting Diode) including an organic light emitting layer, a quantum dot light emitting diode (Quantum dot LED) including a quantum dot light emitting layer, an inorganic light emitting diode (Inorganic LED) including an inorganic semiconductor, or a micro light emitting diode (Micro LED) but embodiments according to the present disclosure are not limited to. In the following drawings, the spontaneous light emitting element is illustrated as an organic light emitting diode.

The non-display area NDA may be an area outside the display area DA. The non-display area NDA may be defined as an edge area of the main area MA of the display panel 100. The non-display area NDA may include a gate driver that supplies gate signals to the gate lines and fan out lines that connect the display driver 200 to the display area DA.

The sub-area SBA may be an area extending from one side of the main area MA. The sub-area SBA may include a flexible material capable of bending, folding, rolling, and the like. For example, when the sub-area SBA is bent, the sub-area SBA may overlap the main area MA in the thickness direction (third direction Z). The sub-area SBA may include a pad portion connected to the display driver 200 and the circuit board 300. According to some embodiments, the sub-area SBA may be omitted, and the display driver 200 and the pad portion may be located in the non-display area NDA.

The display driver 200 may output signals and voltages for driving the display panel 100. The display driver 200 may supply data voltages to data lines. The display driver 200 may supply a power voltage to a power supply line and a gate control signal to the gate driver. The display driver 200 may be formed of an integrated circuit (IC) and may be mounted on the display panel 100 using a chip on glass (COG) method, a chip on plastic (COP) method, or an ultrasonic bonding method. For example, the display driver 200 may be located in the sub-area SBA and may overlap the main area MA in the thickness direction by bending the sub-area SBA. In another example, the display driver 200 may be mounted on the circuit board 300.

The circuit board 300 may be attached to the pad portion of the display panel 100 using an anisotropic conductive film (ACF). Lead lines of the circuit board 300 may be electrically connected to the pad portion of the display panel 100. The circuit board 300 may be a flexible film, such as a flexible printed circuit board, a printed circuit board, or a chip on film.

The touch driver 400 may be mounted on the circuit board 300. The touch driver 400 may be connected to the touch sensing portion of the display panel 100. The touch driver 400 may supply a touch drive signal to a plurality of touch electrodes of the touch sensing portion and may sense a change in capacitance between the plurality of touch electrodes. For example, the touch driving signal may be a pulse signal with a frequency (e.g., a set or predetermined frequency). The touch driver 400 may calculate an input status and an input coordinate based on the amount of change in capacitance between the plurality of touch electrodes. The touch driver 400 may be formed as an integrated circuit (IC).

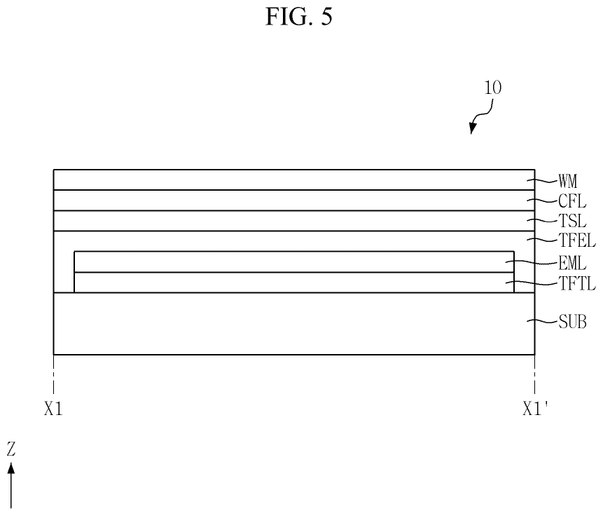

FIG. 5 is a cross-sectional view illustrating an example of a display panel cut along the line X1-X1′ of FIG. 4.

Referring to FIG. 5, the display device 10 may include a substrate SUB, a thin film transistor layer TFTL, a light emitting element layer EML, a thin film encapsulation layer TFEL, a touch electrode layer TSL, a color filter layer CFL, and a cover window WM located on the substrate SUB.

The substrate SUB may be made of an insulating material such as polymer resin. For example, the substrate SUB may be made of polyimide. The substrate SUB may be a flexible substrate capable of bending, folding, rolling, and the like.

The thin film transistor layer TFTL may be located on the substrate SUB.

The thin film transistor layer TFTL may be located on the display panel 100 and the sub-area SBA and may include thin film transistors.

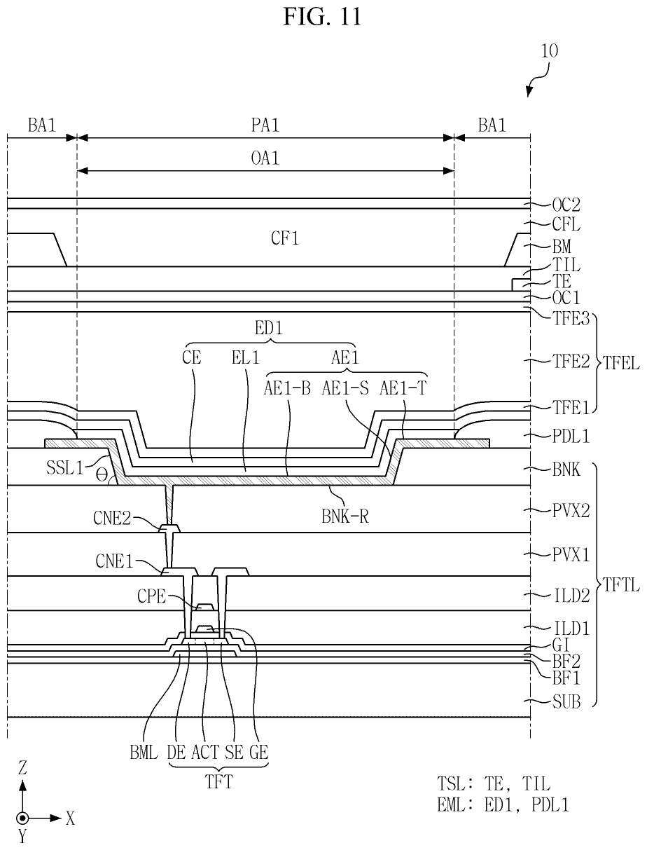

In the transistor layer TFTL, not only thin film transistors TFT of each pixel, but also scan lines and data lines may be formed. As shown in FIG. 11, each of the thin film transistors TFT may include a gate electrode GE, a semiconductor layer ACT, a source electrode SE, and a drain electrode DE.

The light emitting element layer EML may be located on the thin film transistor layer TFTL. The light emitting element layer EML may include light emitting elements ED including a pixel electrode AE, a light emitting layer EL, and a common electrode CE, and a pixel definition layer PDL defining a light emitting area EA, as shown in FIG. 11. The light emitting layer EL may be an organic light emitting layer containing an organic material. In this case, the light emitting layer may include a hole transporting layer, an organic light emitting layer, and an electron transporting layer.

When a voltage (e.g., a set or predetermined voltage) is applied to the pixel electrode AE through the thin film transistor TFT of the thin film transistor layer TFTL and a cathode voltage is applied to the common electrode CE, holes and electrons move to the organic light emitting layer through the hole transport layer and electron transport layer, respectively, and combine with each other in the organic light emitting layer to emit light.

The thin film encapsulation layer TFEL may be located on the light emitting element layer EML. The thin film encapsulation layer TFEL may be arranged to cover the thin film transistor layer TFTL and the light emitting element layer EML.

The thin film encapsulation layer TFEL may include at least one inorganic layer to prevent or reduce instances of contaminants such as oxygen or moisture penetrating into the light emitting element layer EML. The inorganic layer may be a silicon nitride layer, a silicon oxynitride layer, a silicon oxide layer, a titanium oxide layer, or an aluminum oxide layer, but embodiments according to the present disclosure are not limited thereto. In addition, the thin film encapsulation layer 170 may include at least one organic film to protect the light emitting element layer EML from foreign matter, such as dust. The organic film may be an acrylic resin, an epoxy resin, a phenolic resin, a polyamide resin, or a polyimide resin, but embodiments according to the present disclosure are not limited thereto.

The touch electrode layer TSL may be located on the thin film encapsulation layer TFEL. By arranging the touch electrode layer TSL directly on the thin film encapsulation layer TFEL, the thickness of the display device 10 may be reduced compared to the case where a separate touch panel including the touch electrode layer TSL is attached on the thin film encapsulation layer TFEL.

The touch electrode layer TSL may include touch electrodes for detecting a user's touch in a capacitive manner. For example, the touch electrode layer TSL may detect the user's touch using touch electrodes in at least one of a self-capacitance method or a mutual capacitance method.

A color filter layer CFL may be located on the touch electrode layer TSL.

According to some embodiments, the color filter layer CFL may include a light blocking pattern that overlaps the color filter.

A cover window 700 may be located on the color filter layer CFL. In this case, the color filter layer CFL and the cover window 700 may be attached by an adhesive member such as an optically cleared adhesive film (OCA) or an optically cleared resin (OCR).

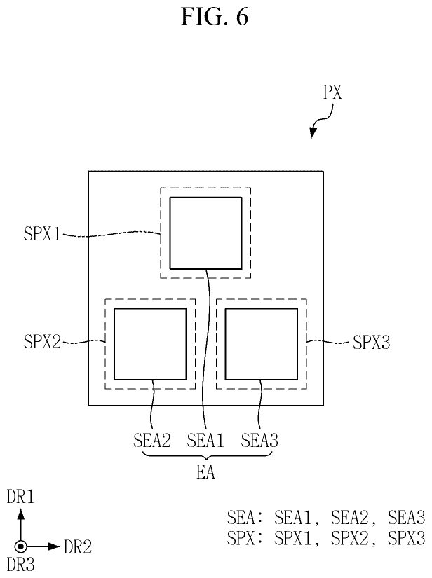

FIGS. 6 to 10 are plan views illustrating pixels PX according to various embodiments. For example, FIGS. 6 to 10 illustrate different embodiments with respect to the configuration, shape and/or arrangement structure of the pixels PX that may be provided or arranged in the display area DA of FIGS. 1 to 5.

Referring to FIGS. 6 to 10, the pixel PX may include at least two sub-pixels SPX, each of which includes sub-emission areas SEA. The pixel PX may include a light emitting area EA including sub-emission areas SEA of the sub-pixels SPX. For example, the light emitting area EA of each pixel PX may be formed of the sub-emission areas SEA of the sub-pixels SPX provided within the pixel PX.

Each sub-pixel SPX may include at least one light emitting element (e.g., an organic light emitting diode) provided in each sub-emission area SEA. According to some embodiments, each sub-pixel SPX may further include a pixel circuit connected to each light emitting element. According to some embodiments, the term “connection” may include physical connection and/or an electrical connection.

According to some embodiments, the pixel PX includes a first color sub-pixel SPX1 (also referred to as “first sub-pixel”) that emits light of a first color (e.g., red light), and a second color sub-pixel SPX2 (also referred to as the “second sub-pixel”) that emits light of a second color (e.g., green light), and a third color sub-pixel SPX3 (also referred to as “third sub-pixel”) that emits light of a third color (e.g. blue light).

The first color sub-pixel SPX1 may include a first color sub-emission area SEA1 (e.g., a light emitting area of the first color sub-pixel SPX1) provided with a light emitting element (e.g., an organic light emitting diode) and emitting light of a first color. According to some embodiments, the first color sub-pixel SPX1 may include a light emitting element (e.g., a red organic light emitting diode) that emits light of the first color or may include a light emitting element that emits light of a specific color and a wavelength conversion element that converts light of the specific color to light of the first color, or the like. Accordingly, light of the first color may be emitted from the first color sub-emission area SEA1.

The second color sub-pixel SPX2 may include a second color sub-emission area SEA2 (e.g., a light emitting area of the second color sub-pixel SPX2) provided with a light emitting element (e.g., an organic light emitting diode) and emitting light of a second color. According to some embodiments, the second color sub-pixel SPX2 may include a light emitting element (e.g., a green organic light emitting diode) that emits light of the second color or may include a light emitting element that emits light of a specific color and a wavelength conversion element that converts light of the specific color to light of the second color, or the like. Accordingly, light of the second color may be emitted from the second color sub-emission area SEA2.

The third color sub-pixel SPX3 may include a third color color sub-emission area SEA3 (e.g., a light emitting area of the third color sub-pixel SPX3) provided with a light emitting element (e.g., an organic light emitting diode) and emitting light of a third color. According to some embodiments, the third color sub-pixel SPX3 may include a light emitting element (e.g., a blue organic light emitting diode) that emits light of a third color or may include a light emitting element that emits light of a specific color and a wavelength conversion element that converts light of the specific color to light of the third color, or the like. Accordingly, light of the third color may be emitted from the third color sub-emission area SEA3.

FIGS. 6 to 10 illustrate embodiments in which a single pixel PX is provided with a first sub-pixel SPX1, a second sub-pixel SPX2, a third sub-pixel SPX3, and/or a fourth sub-pixel SPX4, respectively, but embodiments according to the present disclosure are not limited thereto. For example, two or more sub-pixels SPX that emit light of the same color may be provided within a single pixel PX. The type and/or number of sub-pixels SPX included in each pixel PX may be varied in different embodiments.

Each sub-pixel SPX may include a sub-emission area SEA having a rectangular shape, a non-rectangular polygonal shape, a circular shape, an elliptical shape, or another shape. For example, the shape, size, ratio, and/or arrangement structure of the sub-emission area SEA provided to each pixel PX may be varied to achieve target values for various characteristics such as aperture, transmittance, luminous efficiency, white balance, and/or visibility of each sub-pixel SPX and the pixel PX including it.

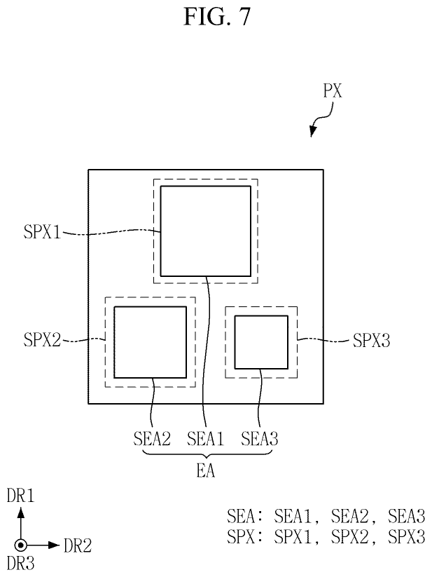

According to some embodiments, the pixel PX may each include sub-emission area SEA having a rectangular shape, such as a square, and arranged in a delta shape, as shown in FIGS. 6 and 7. According to some embodiments, the sub-emission area SEA provided in each pixel PX may have substantially the same or similar size to each other as shown in FIG. 6. According to some embodiments, at least two sub-emission areas SEA provided in each pixel PX may have different sizes. For example, as shown in FIG. 7, the sub-emission areas SEA provided in each pixel PX may have different sizes.

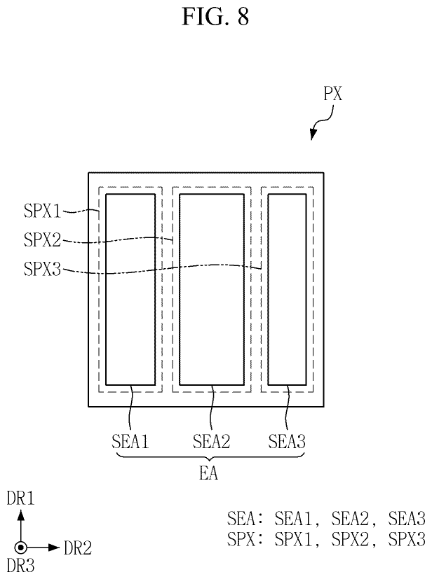

According to some embodiments, the pixel PX may include sub-emission areas SEA arranged in a stripe shape along one direction. For example, the pixel PX has sub-emission areas SEA each having a rectangular shape extending in the first direction DR1 and sequentially arranged along the second direction DR2 as shown in FIG. 8. According to some embodiments, the first color sub-emission area SEA1, the second color sub-emission area SEA2, and the third color sub-emission area SEA3 may be sequentially arranged along the second direction DR2 but the order of arrangement of the sub-emission area SEA may be varied. The sub-emission areas SEA may have the same area as each other or may have different areas.

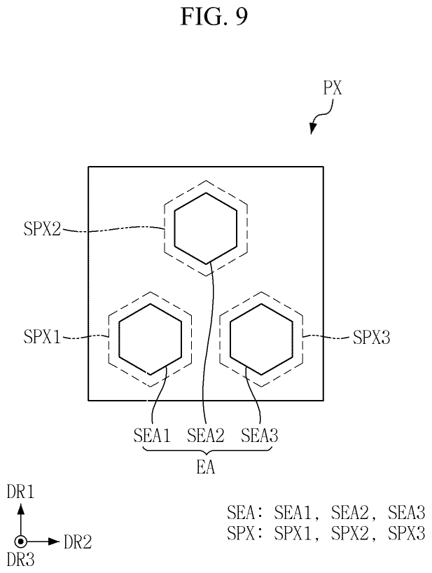

According to some embodiments, the pixel PX may include sub-emission areas SEA having a non-rectangular shape. For example, the pixel PX may have a non-rectangular polygonal shape (e.g., a pentagon) and may include sub-emission areas SEA arranged in a delta shape, as shown in FIG. 9. The sub-emission areas SEA may have the same area as each other or may have different areas. The order of arrangement of the sub-emission areas SEA may be varied in different embodiments.

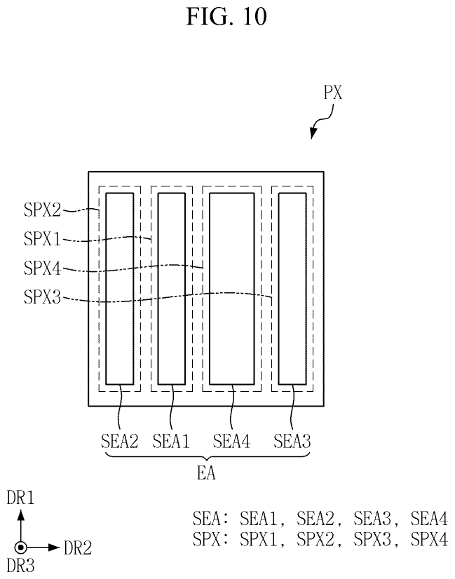

According to some embodiments, the pixel PX may further include a fourth color sub-pixel SPX4 (also referred to as a “fourth sub-pixel”) that emits a fourth color of light (e.g., white light), as shown in FIG. 10. The fourth color sub-pixel SPX4 may include a fourth color sub-emission areas SEA4 (e.g., a light emitting area of the fourth color sub-pixel SPX4) provided with a light emitting element (e.g., an organic light emitting diode) and emitting light of the fourth color. According to some embodiments, the fourth color sub-pixel SPX4 may include a light emitting element (e.g., a white organic light emitting diode) that emits light of the fourth color or may include a light emitting element that emits light of a specific color and a wavelength conversion element that converts light of the specific color to light of the fourth color, or the like. Accordingly, light of the fourth color may be emitted from the fourth color sub-emission area SEA4. According to some embodiments, the pixel PX may include sub-emission areas SEA each having a rectangular shape extending in the first direction DR1 and arranged sequentially along the second direction DR2. According to some embodiments, a second color sub-emission area SEA2, a first color sub-emission area SEA1, a fourth color sub-emission area SEA4, and a third color sub-emission area SEA3 may be sequentially arranged along the second direction DR2, but the order of arrangement of the sub-emission areas SEA may be varied. The sub-emission areas SEA may have the same area or different areas.

The display device 10 may include pixels PX having various configurations, structures, and/or shapes in addition to the embodiments of FIGS. 6 to 10.

FIG. 11 is a cross-sectional view illustrating aspects of a display device according to some embodiments.

As the substrate SUB was mentioned above, detailed description will be omitted.

The thin film transistor layer TFTL may include a first buffer layer BF1, a bottom metal layer BML, a second buffer layer BF2, a thin film transistor TFT, a gate insulating layer GI, a first interlayer insulating layer ILD1, a capacitor electrode CPE, a second interlayer insulating layer ILD2, a first connection electrode CNE1, a first protective layer PVX1, a second connection electrode CNE2, a second protective layer PVX2, and a bank layer BNK.

The first buffer layer BF1 may be located on the substrate SUB. The first buffer layer BF1 may include an inorganic film that may prevent or reduce instances of contaminants such as air or moisture penetrating. For example, the first buffer layer BF1 may include a plurality of inorganic films alternately stacked.

The bottom metal layer BML may be located on the first buffer layer BF1. For example, the bottom metal layer BML may be formed as a single layer or multiple layers of any one of molybdenum (Mo), aluminum (AI), chromium (Cr), gold (Au), titanium (Ti), nickel (Ni), neodymium (Nd), and copper (Cu), or an alloy thereof.

The second buffer layer BF2 may cover the first buffer layer BF1 and the bottom metal layer BML. The second buffer layer BF2 may include an inorganic film that may prevent or reduce penetration of contaminants such as air or moisture. For example, the second buffer layer BF2 may include a plurality of inorganic films alternately stacked.

The thin film transistor TFT may be located on the second buffer layer BF2 and may form a pixel circuit for each of a plurality of pixels. For example, the thin film transistor TFT may be a driving transistor or switching transistor of the pixel circuit. The thin film transistor TFT may include a semiconductor layer ACT, a source electrode SE, a drain electrode DE, and a gate electrode GE.

The semiconductor layer ACT may be located on the second buffer layer BF2. The semiconductor layer ACT may overlap the bottom metal layer BML and the gate electrode GE in the thickness direction and may be insulated from the gate electrode GE by the gate insulating layer GI. A portion of the semiconductor layer ACT may have the material of the semiconductor layer ACT conductive to form the source electrode SE and the drain electrode DE.

The gate electrode GE may be located on the gate insulating layer GI. The gate electrode GE may overlap the semiconductor layer ACT with the gate insulating layer GI interposed therebetween.

The gate insulating layer GI may be located on the semiconductor layer ACT. For example, the gate insulating layer GI may cover the semiconductor layer ACT and the second buffer layer BF2 and may insulate the semiconductor layer ACT and the gate electrode GE. The gate insulating layer GI may include a contact hole through which the first connection electrode CNE1 penetrates.

The first interlayer insulating layer ILD1 may cover the gate electrode GE and the gate insulating layer GI. The first interlayer insulating layer ILD1 may include a contact hole through which the first connection electrode CNE1 penetrates. The contact hole of the first interlayer insulating layer ILD1 may be connected to the contact hole of the gate insulating layer GI and the contact hole of the second interlayer insulating layer ILD2.

The capacitor electrode CPE may be located on the first interlayer insulating layer ILD1. The capacitor electrode CPE may overlap the gate electrode GE in the thickness direction. The capacitor electrode CPE and the gate electrode GE may form electrostatic capacitance.

The second interlayer insulating layer ILD2 may cover the capacitor electrode CPE and the first interlayer insulating layer ILD1. The second interlayer insulating layer ILD2 may include a contact hole through which the first connection electrode CNE1 penetrates. The contact hole of the second interlayer insulating layer ILD2 may be connected to the contact hole of the first interlayer insulating layer ILD1 and the contact hole of the gate insulating layer GI.

The first connection electrode CNE1 may be located on the second interlayer insulating layer ILD2. The first connection electrode CNE1 may electrically connect the drain electrode DE of the thin film transistor TFT and the second connection electrode CNE2. The first connection electrode CNE1 may be inserted into the contact hole formed in the second interlayer insulating layer ILD2, the first interlayer insulating layer ILD1, and the gate insulating layer GI to contact the drain electrode DE of the thin film transistor TFT.

The first protective layer PVX1 may cover the first connection electrode CNE1 and the second interlayer insulating layer ILD2. The first protective layer PVX1 may protect the thin film transistor TFT. The first protective layer PVX1 may include a contact hole through which the second connection electrode CNE2 penetrates.

The second connection electrode CNE2 may be located on the first protective layer PVX1. The second connection electrode CNE2 may electrically connect the first connection electrode CNE1 and the first pixel electrode AE1 of the first light emitting element ED1. The second connection electrode CNE2 may be inserted into a contact hole formed in the first protective layer PVX1 to contact the first connection electrode CNE1.

The second protective layer PVX2 may cover the second connection electrode CNE2 and the first protective layer PVX1. The second protective layer PVX2 may include a contact hole through which the first pixel electrode AE1 of the first light emitting element ED1 penetrates.

The bank layer BNK may be located on the second protective layer PVX2. The bank layer BNK may include a plurality of openings. The plurality of openings may penetrate the bank layer BNK to expose the second protective layer PVX2 but is not limited thereto.

The bank layer BNK has a sloped surface SSL1 that defines a downwardly concave recess BNK-R. Further, the sloped surface SSL1 of the bank layer BNK may have a gentle slope with respect to the top surface of the bank layer BNK. The sloped surface SSL1 of the bank layer BNK and the downwardly extending line of the recess BNK-R have an inclination angle θ. The inclination angle θ may be an acute angle. The inclination angle θ may in a range of 20 degrees to 70 degrees (or about 20 degrees to about 70 degrees), but embodiments according to the present disclosure are not limited thereto. The recess BNK-R may have an upper width that is wider (e.g., substantially wider) than the lower width. As such, the bank layer BNK may have an inclined structure defined by the recess BNK-R.

According to some embodiments, the bank layer BNK is shown as a single insulating layer, but the bank layer BNK may be composed of a plurality of insulating layers. For example, the bank layer BNK may include a first bank layer and a second bank layer. The second bank layer may be located on the first bank layer, and the second bank layer may have a recess exposing the first bank layer.

The bank layer BNK may be formed from an organic material, such as an acrylic resin, an epoxy resin, a phenolic resin, a polyamide resin, a polyimide resin, or the like.

The light emitting element layer EML may be located on the thin film transistor layer TFTL. The light emitting element layer EML may include a first light emitting element ED1 and a first pixel definition layer PDL1. The first light emitting element ED1 may include a first pixel electrode AE1, a first light emitting layer EL1, and a common electrode CE.

The first pixel electrode AE1 may be arranged to overlap one of the recesses BNK-R defined by the bank layer BNK. The first pixel electrode AE1 is arranged along the sloped surface of the bank layer BNK. Accordingly, the first pixel electrode AE1 may have an inclined structure. The first pixel electrode AE1 may include a sloped portion AE1-S located on the sloped surface SSL1 of the recess BNK-R of the bank layer BNK, a bottom portion AE1-B connected to the bottom portion of the sloped portion AE1-S, and a top portion AE1-T connected to the top portion of the sloped portion AE1-S and located on the top of the bank layer BNK. The inclination angle of the sloped portion AE1-S of the first pixel electrode AE1 may be the same as the inclination angle of the sloped surface SSL1 of the bank layer BNK. For example, the inclination angle of the sloped portion AE1-S may be 20 to 70 degrees. As the inclination angle increases, the viewing angle narrows, and as the inclination angle decreases, luminance may be relatively improved. The first pixel electrode AE1 may have a concave shape. The sloped portion AE1-S surrounds the bottom portion AE1- B, and the sloped portion AE1-S and the bottom portion AE1-B do not overlap vertically. The bottom portion AE1-B and the top portion AE1-T may be flat but may be formed to have a curvature during the process. Even when the bottom portion AE1-B and top portion AE1-T have curvature during the process, they may be formed to be relatively flat compared to the sloped portion AE1-S.

The first pixel electrode AE1 may be electrically connected to the drain electrode DE of the thin film transistor TFT through the first connection electrode CNE1 and the second connection electrode CNE2.

The pixel defining layer PDL may define a light emitting portion, and their areas or sizes may be different. The first pixel definition layer PDL1 may overlap a first light blocking area BA1 and may be located on a portion of the bank layer BNK and the first pixel electrode AE1. At least a portion of the top portion AE1-T of the first pixel electrode AE1 may be covered by the pixel definition layer PDL.

The first pixel definition layer PDL1 may space and insulate the first pixel electrode AE1 of each of the plurality of first light emitting elements ED1. The first pixel definition layer PDL1 may include a light absorbing material to prevent or reduce light reflection. According to some embodiments, the first pixel definition layer PDL1 may include carbon black. The first pixel definition layer PDL1 including carbon black may include a black color and may absorb light reflected by the electrode.

The first light emitting layer EL1 may be located on a portion of the first pixel electrode AE1 and the first pixel definition layer PDL1. For example, the first light emitting layer EL1 may be located on one surface of the first pixel electrode AE1 exposed by the first opening OP1 formed by the first pixel definition layer PDL1 and on a portion of the first pixel definition layer PDL1. The first light emitting layer EL1 is formed along the first pixel electrode AE1 on the first pixel electrode AE1 and may therefore have an inclined structure.

The first light emitting layer EL1 may be an organic light emitting layer made of an organic material. When the first light emitting layer EL1 corresponds to an organic light emitting layer, the thin film transistor TFT applies a voltage (e.g., a set or predetermined voltage) to the first pixel electrode AE1 of the first light emitting element ED1, and when the common electrode CE of the first light emitting element ED1 receives the common voltage or the cathode voltage, the first light emitting layer EL1 may emit light.

The common electrode CE may be located on the first light emitting layer EL1 in the first light emitting area PA1 and may be located on the first pixel definition layer PDL1 in the first light blocking area BA1. For example, the common electrode CE may be located on the first light emitting layer EL1 and a portion of the first pixel definition layer PDL1 where the first light emitting layer layer EL1 is not located. Further, the common electrode CE may be formed on the entire surface of the display area DA in the form of an electrode common to all pixels rather than being divided into a plurality of pixels.

The common electrode CE may receive a common voltage or a low potential voltage. When the first pixel electrode AE1 receives a voltage corresponding to the data voltage and the common electrode CE receives a low potential voltage, the first light emitting layer EL1 may emit light as a potential difference is formed between the first pixel electrode AE1 and the common electrode CE.

The thin film encapsulation layer TFEL may be located on the common electrode CE to cover the plurality of first light emitting elements ED1. According to some embodiments, the thin film encapsulation layer TFEL may include at least one inorganic film and at least one organic film to prevent or reduce instances of foreign substances or contaminants such as oxygen, moisture, or dust penetrating into the light emitting element layer EML.

According to some embodiments, the thin film encapsulation layer TFEL may include a first thin film encapsulation layer TFE1, a second thin film encapsulation layer TFE2, and a third thin film encapsulation layer TFE3 sequentially stacked in the third direction Z. The first thin film encapsulation layer TFE1 and the third thin film encapsulation layer TFE3 may be inorganic layers, and the second thin film encapsulation layer TFE2 located between them may be an organic layer.

The first thin film encapsulation layer TFE1 and the third thin film encapsulation layer TFE3 may each include one or more inorganic insulating materials. In one example, the inorganic insulating material may include aluminum oxide, titanium oxide, tantalum oxide, hafnium oxide, zinc oxide, silicon oxide, silicon nitride, and/or silicon oxynitride.

The second thin film encapsulation layer TFE2 may include a polymer-based material. Polymer-based materials may include acrylic resins, epoxy resins, polyimides, and polyethylene, among others. For example, an organic encapsulation layer 320 may include an acrylic resin, such as polymethylmethacrylate, polyacrylic acid, or the like. The second thin film encapsulation layer TFE2 may be formed by curing a monomer or applying a polymer.

A first overcoat layer OC1 may be located on the third thin film encapsulation layer TFE3. The first overcoat layer OC1 may have a relatively lower dielectric constant than the second thin film encapsulation layer TFE2, thereby increasing the sensitivity of the touch electrode layer TSL, which will be described in more detail below. For example, the dielectric constant of the first overcoat layer OC1 may be 2 F/m but is not limited thereto.

A touch electrode layer TSL may be located on the first overcoat layer OC1. The touch electrode layer TSL may include a touch insulating layer TIL and a touch electrode TE.

The touch electrode TE may include a driving electrode and a sensing electrode. The driving electrode and the sensing electrode may be formed as a monolayer of molybdenum (Mo), titanium (Ti), copper (Cu), aluminum (AI), and indium tin oxide (ITO), respectively, or may be formed as a laminated structure of aluminum and titanium (Ti/Al/Ti), a laminated structure of aluminum and ITO (ITO/AI/ITO), an APC alloy, and a laminated structure of APC alloy and ITO (ITO/APC/ITO). The touch insulating layer TIL may include an inorganic film and/or an organic film and may cover the touch electrode TE.

The touch insulating layer TIL may have insulated and optical functions and may include, for example, an inorganic film including at least one of a silicon nitride layer, a silicon oxynitride layer, a silicon oxide layer, a titanium oxide layer, or an aluminum oxide layer. According to some embodiments, the touch electrode layer TSL may be omitted.

The color filter layer CFL may be located on the touch insulating layer TIL, and the color filter layer CFL may include a color filter CF and a light blocking pattern BM. According to some embodiments in which the touch electrode layer TSL is omitted, the color filter layer CFL may be located on the first overcoat layer OC1.

The light blocking pattern BM may be located on the touch insulating layer TIL, overlapping the first light blocking area BA1. The light blocking pattern BM may include a light absorbing material. For example, the light blocking pattern BM may include an inorganic black pigment or an organic black pigment. The inorganic black pigment may be Carbon Black, and the organic black pigment may include at least one of Lactam Black, Perylene Black, or Aniline Black but is not limited. The light blocking pattern BM may relatively improve the color gamut of the display device 10 by preventing or reducing visible light from intruding and mixing between the first to fourth light emitting portions RE1, GE11, BE1, and GE12.

According to some embodiments, the first pixel definition layer PDL1 and the light blocking pattern BM may partially block light emitted from the light emitting element layer EML. Accordingly, only light having a light path that does not overlap the first pixel definition layer PDL1 and the light blocking pattern BM may be emitted to the outside of the display device 10.

According to some embodiments, the first color filter CF1 of the color filter layer CFL may be located on the light blocking pattern BM and the touch insulating layer TIL. The first color filter CF1 may be arranged to correspond to different light emitting areas, respectively.

According to some embodiments, the first color filter CF1 may selectively transmit light of a specific color and block or absorb light of a specific color. For example, if the first color filter CF1 is a red color filter, it may transmit red light and block or transmit blue and green light but is not limited thereto.

The second overcoat layer OC2 may be located on the color filter layer CFL. The second overcoat layer OC2 may be a colorless transmissive layer that does not have a color in the visible light band. For example, the second overcoat layer OC2 may include a colorless, light transmitting organic material such as a resin of the acrylic family.

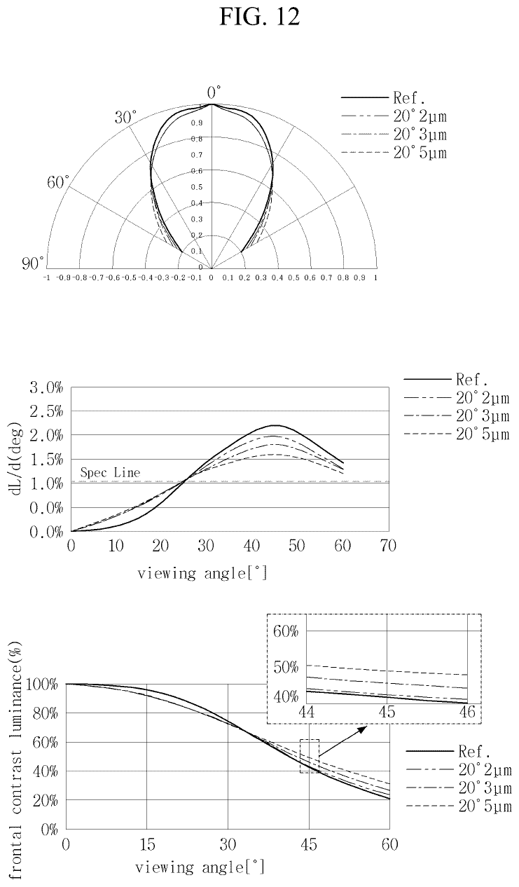

FIG. 12 is a graph to illustrate the correlation between the horizontal width of the inclined portion, the luminance ratio deviation dLvA, and the frontal contrast luminance in the display device according to some embodiments as illustrated in FIG. 11.

The graph of FIG. 12 illustrates the luminance ratio deviation dLvA and the frontal contrast luminance as a function of the width of the horizontal direction of the sloped portion AE1-S in a display device according to some embodiments as illustrated in FIG. 11 with the inclination of the sloped portion AE1-S fixed.

According to some embodiments, the inclination of the sloped portion AE1-S is set to 20°, and the luminance ratio deviation (dL/d) and the frontal contrast luminance are shown as the width of the horizontal direction of the sloped portion AE1-S increases to 2 μm, 3 μm, and 5 μm. At a viewing angle of 40° to 50°, the luminance ratio deviation (dL/d) decreases significantly as the width d1 in the horizontal direction of the first sloped portion AE1-S1 increases to an extension distance of 2 μm, 3 μm, and 5 μm. In addition, at a viewing angle of 40° to 50°, the frontal contrast luminance increases as the width d1 in the horizontal direction of the first sloped portion AE1-S1 increases to an extension distance of 2 μm, 3 μm, and 5 μm.

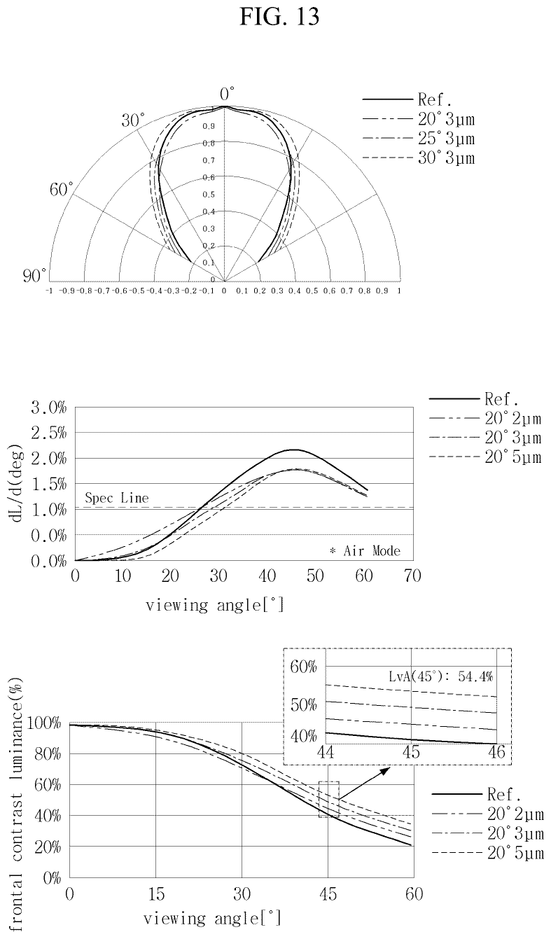

FIG. 13 is a graph to illustrate the correlation between the slope of the slope, the luminance ratio deviation dLvA, and the frontal contrast luminance in the display device according to some embodiments as illustrated in FIG. 11.

The graph of FIG. 13 illustrates the luminance ratio deviation dLvA and the frontal contrast luminance as a function of the inclination θ of the sloped portion AE1-S in the display device according to some embodiments as illustrated in FIG. 11, with the width of the sloped portion AE1-S in the horizontal direction fixed. According to some embodiments, the horizontal width of the sloped portion AE1-S is 3 μm, and the luminance ratio deviation (dL/d) and frontal contrast luminance are compared when the inclination θ of the sloped portion AE1-S is increased to 20°, 25°, and 30°. The frontal contrast luminance increases as the inclination θ of the sloped portion AE1-S increases to 20°, 25°, and 30°. For example, at a viewing angle of 40° to 50°, the frontal contrast luminance increases significantly as the inclination θ of the sloped portion AE1-S increases to 20°, 25°, and 30°. On the other hand, at a viewing angle of 40° to 50°, the luminance ratio deviation dLvA does not change significantly as the inclination θ of the sloped portion AE1-S increases to 20°, 25°, and 30°.

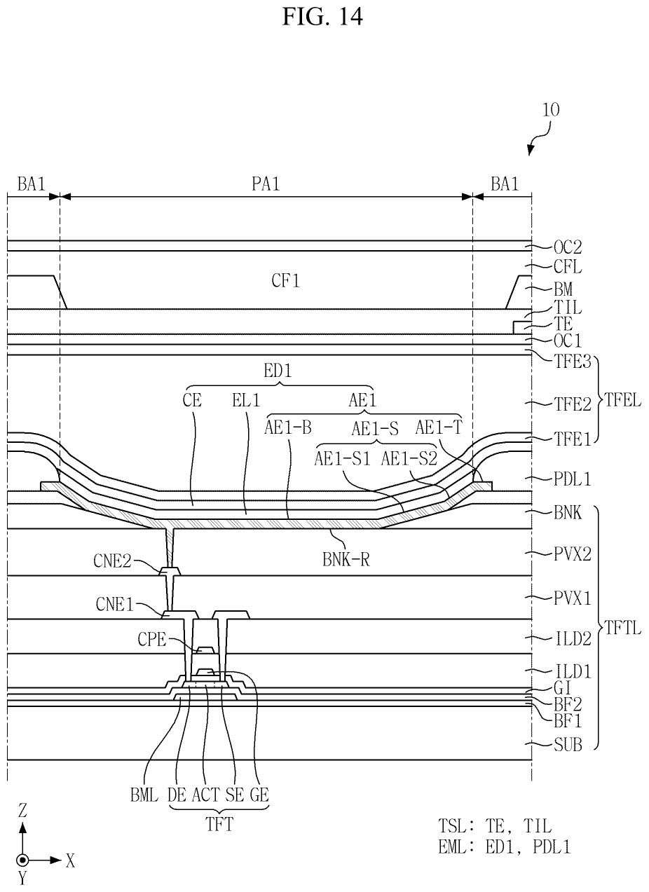

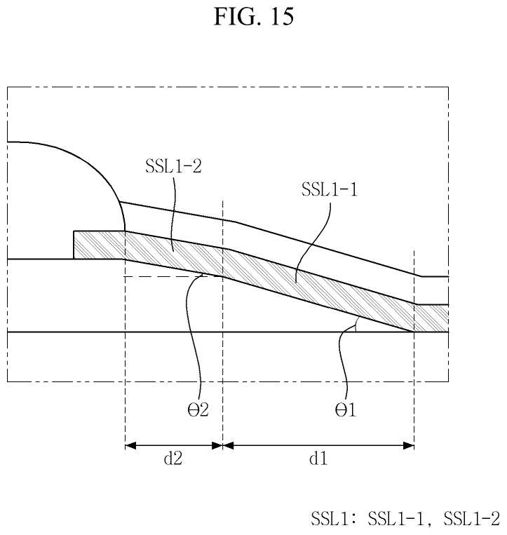

FIG. 14 is a cross-sectional view illustrating a display device according to some embodiments. FIG. 15 is an enlarged view to illustrate the multi-stage inclined structure of the pixel electrodes of FIG. 14.

The display device illustrated with reference to FIG. 14 is different from the display device of FIG. 11 in that the bank layer BNK and the first light emitting element ED1 have multi-stage sloped portions AE1-S.

Referring to FIGS. 14 and 15, the bank layer BNK has a multi-stage inclined structure. The multi-stage inclined structure includes sloped surfaces SSL1 having different slopes. For example, the inclined structure has a first sloped surface SSL1-1 with a first inclination θ1 and a second sloped surface SSL1-2 having a second inclination θ2. The second sloped surface SSL1-2 extends upward from the first sloped surface SSL1-1. The second inclination θ2 may be smaller than the first inclination θ1. For example, the first inclination θ1 may be approximately 20° to 30° and the second inclination θ2 may be 5° to 15°.

The first pixel electrode AE1 may be arranged to overlap one of the plurality of recesses BNK-R defined by the bank layer BNK. The first pixel electrode AE1 is arranged along the sloped surface SSL1 of the bank layer BNK. Accordingly, the first pixel electrode AE1 may have a multi-stage inclined structure. For example, the first pixel electrode AE1 is a structure in which the first sloped portion AE1-S1 having a first inclination θ1 and the second sloped portion AE1-S2 having a second inclination θ2 are stepped. The second sloped portion AE1-S2 extends upward from the first sloped portion AE1-S1. The first pixel electrode AE1 may include a top portion AE1-T connected to the top of the second sloped portion AE1-S2 and located on the top of the bank layer BNK, and a bottom portion AE1-B connected to the bottom of the first sloped portion AE1-S1.

The first sloped portion AE1-S1 has a first inclination θ1, and the second sloped portion AE1-S2 extends from the first sloped portion AE1-S1 and on top and has a second inclination θ2. The second inclination θ2 may be formed more gently than the first inclination θ1. The second inclination θ2 may be smaller than the first inclination θ1. For example, the first inclination θ1 may be 20° to 30°, and the second inclination θ2 may be 5° to 15°.

The horizontal width d1 of the first sloped portion AE1-S1 may be longer than the horizontal width d2 of the second sloped portion AE1-S2. For example, the horizontal width d1 of the first sloped portion AE1-S1 is 3 μm to 5 μm, and the horizontal width d2 of the second sloped portion AE1-S2 is 1 μm to 3 μm.

The first light emitting layer EL1 may be located on a portion of the first pixel electrode AE1 and the first pixel definition layer PDL1. For example, the first light emitting layer EL1 may be located on one surface of the first pixel electrode AE1 and a portion of the first pixel definition layer PDL1 exposed by the first opening OP1 formed by the first pixel definition layer PDL1. The first light emitting layer EL1 is formed on the first pixel electrode AE1 and along the first pixel electrode AE1, so it may have a multi-stage inclined structure. The first light emitting layer EL1 may overlap the bottom portion AE1-B, the first sloped portion AE1-S1, and the second sloped portion AE1-S2 of the first pixel electrode AE1. According to some embodiments, the first light emitting layer EL1 may overlap the top end AE1-T of the first pixel electrode AE1.

The first light emitting layer EL1 may be an organic light emitting layer made of an organic material. When the first light emitting layer EL1 corresponds to an organic light emitting layer, the first light emitting layer EL1 may emit light when the thin film transistor TFT applies a voltage (e.g., a set or predetermined voltage) to the first pixel electrode AE1 of the first light emitting element ED1, and the common electrode CE of the first light emitting element ED1 receives a common voltage or cathode voltage.

The common electrode CE may be located on the first light emitting layer EL1 in the first light emitting area PA1 and may be located on the first pixel definition layer PDL1 in the first light blocking area BA1.

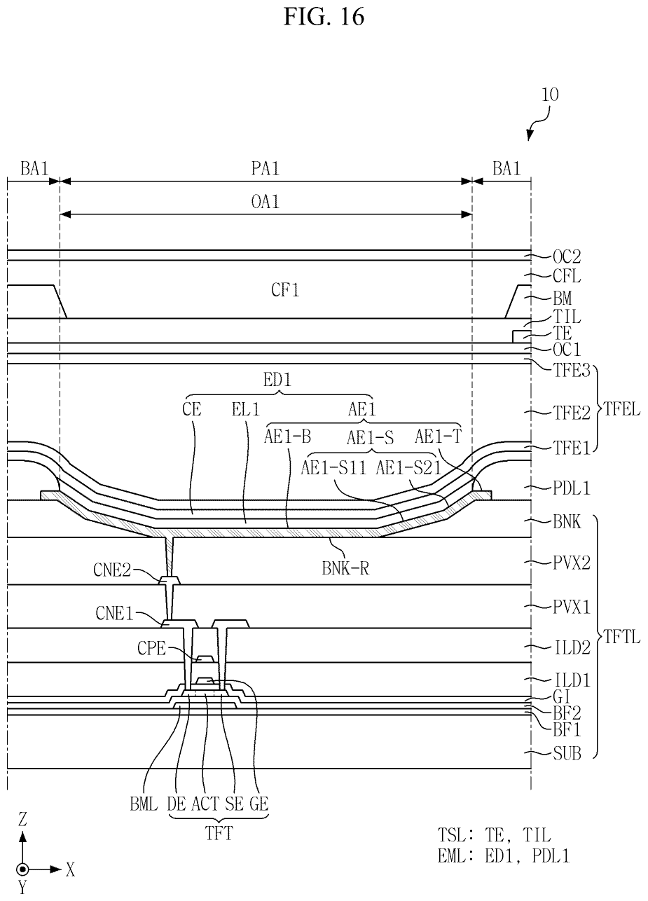

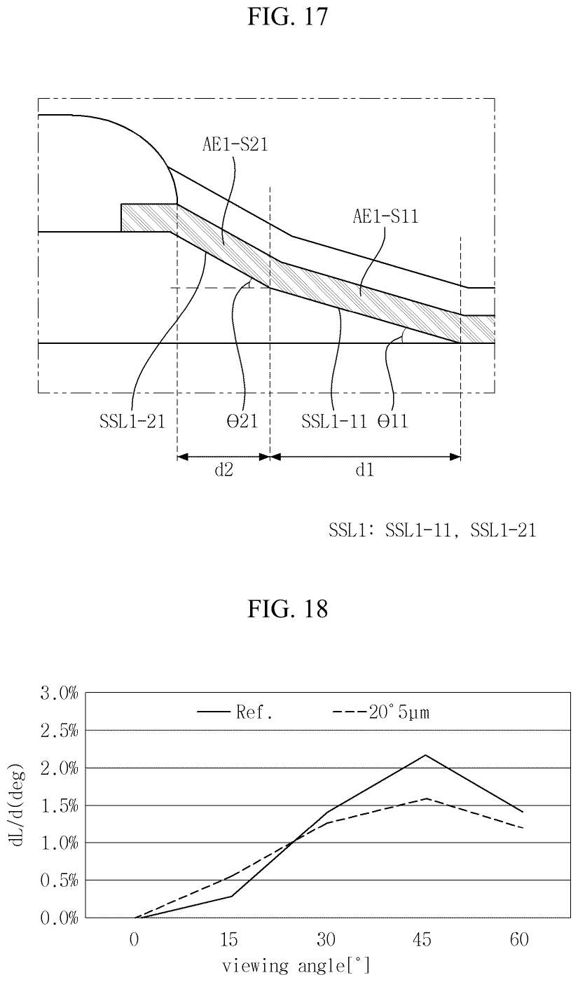

FIG. 16 is a cross-sectional view illustrating a display device according to some embodiments. FIG. 17 is an enlarged view to illustrate the multi-stage inclined structure of the pixel electrode of FIG. 12.

The display device illustrated with reference to FIG. 16 is different from the display device of FIG. 11 in that the bank layer BNK and the first light emitting element ED1 have multi-stage sloped portions AE1-S.

Referring to FIGS. 16 and 17, the bank layer BNK has a multi-stage inclined structure. The multi-stage inclined structure sloped structure SSL1 having different slopes. For example, the inclined structure has a first sloped surface SSL1-11 with a first inclination θ11 and a second sloped surface SSL1-21 with a second inclination θ21. The second sloped surface SSL1-21 extends upward from the first sloped surface SSL1-11. The second inclination θ21 may be greater than the first inclination θ11. For example, the first inclination θ11 may be approximately 20° to 30° and the second inclination θ21 may be 30° to 60°.

The first pixel electrode AE1 may be arranged to overlap one of the plurality of recesses BNK-R defined by the bank layer BNK. The first pixel electrode AE1 is arranged along the sloped surface SSL1 of the bank layer BNK. Accordingly, the first pixel electrode AE1 may have a multi-stage inclined structure. For example, the first pixel electrode AE1 is a structure in which the first sloped portion AE1-S11 having a first inclination θ11 and the second sloped portion AE1-S21 having a second inclination θ21 are stepped. The second sloped portion AE1-S21 extends upward from the first sloped portion AE1-S11. The first pixel electrode AE1 may include a top portion AE1-T connected to the top of the second sloped portion AE1-S21 and located on the top of the bank layer BNK, and a bottom portion AE1-B connected to the bottom of the first sloped portion AE1-S1.

The first sloped portion AE1-S11 has a first inclination θ11, and the second sloped portion AE1-S21 extends from the first sloped portion AE1-S11 and is located at the top portion and has a second inclination θ21. The second inclination θ21 may be steeper than the first inclination θ11. For example, the first inclination θ11 may be 20° to 30°, and the second inclination θ2 may be 30° to 60°.

The horizontal width d1 of the first sloped portion AE1-S11 may be longer than the horizontal width d2 of the second sloped portion AE1-S21. For example, the horizontal width d1 of the first sloped portion AE1-S11 may be 3 μm˜5 μm, and the horizontal width d2 of the second sloped portion AE1-S21 may be 1 μm˜3 μm.

FIG. 18 is a graph illustrating a luminance ratio deviation of a display device employing a multi-stage inclined structure according to some embodiments as described with reference to FIGS. 16 and 17.

FIG. 18 is a graph illustrating the luminance ratio deviation dLvA according to the viewing angle in a display device adopting a multi-stage inclined structure, and the luminance ratio deviation at a viewing angle of 45 degrees is reduced by about 1.5% compared to an alternative display device.

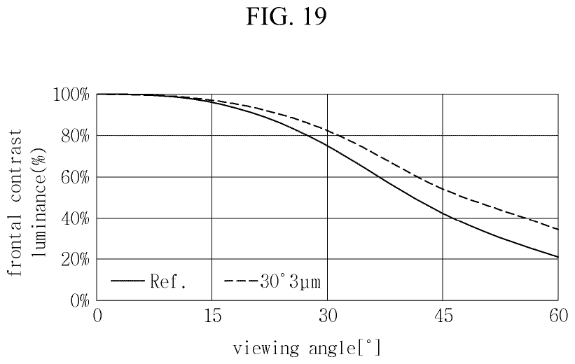

FIG. 19 is a graph illustrating frontal contrast luminance of a display device employing the multi-stage inclined structure described with reference to FIGS. 16 and 17.

FIG. 19 is a graph illustrating the frontal contrast luminance LvA according to the viewing angle in a display device adopting a multi-stage inclined structure and the luminance ratio compared to the front at a viewing angle of 45 degrees is relatively improved by about 57% compared to alternative systems.

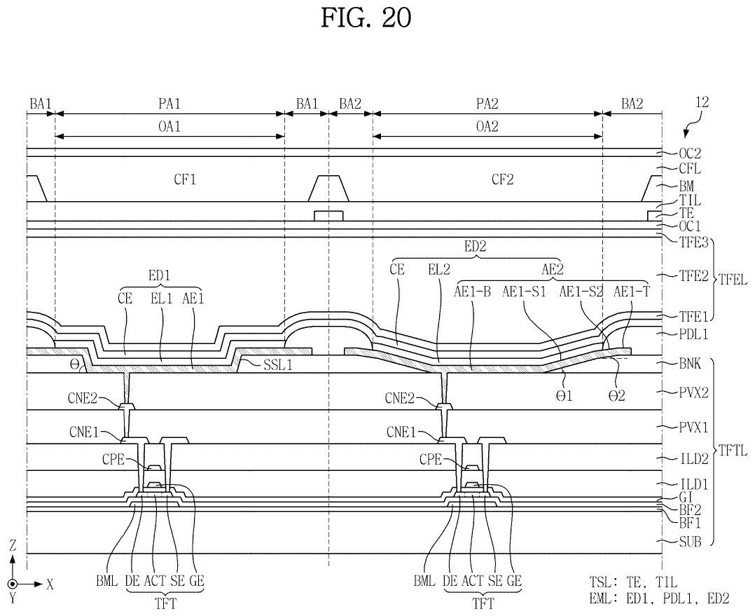

FIG. 20 is a cross-sectional view illustrating a display device including a light emitting area emitting light of different wavelengths, according to some embodiments.

FIG. 20 illustrates a cross-section view across the first light emitting area PA1 and the second light emitting area PA2.

The cross-sectional structure of the display device 11 will be described in more detail with reference to FIG. 20 in addition to FIGS. 1 to 12.

The first light emitting area PA1 and the second light emitting area PA2 may emit light of different wavelengths. For example, the first light emitting area PA1 and the second light emitting area PA2 may emit red or green light, respectively, or blue or green light. However, embodiments according to the present disclosure are not limited thereto.

The first light emitting area PA1 may include the first light emitting element ED1, and the second light emitting area PA2 may include the second light emitting element ED2.

The light emitting elements included in different light emitting areas may have different structures. For example, the first light emitting element ED1 may include a single-layer inclined structure, as described with reference to FIG. 11. As described with reference to FIGS. 14 and 15, the second light emitting element ED2 may include a multi-stage inclined structure.

The first light emitting element ED1 may include a first pixel electrode AE1, a first light emitting layer EL1, and a common electrode CE.

The first pixel electrode AE1 may be arranged to overlap one of the recesses BNK-R defined by the bank layer BNK. The first pixel electrode AE1 is arranged along the sloped surface SSL1 of the bank layer BNK. Accordingly, the first pixel electrode AE1 may have an inclined structure. The first pixel electrode AE1 may include a sloped portion AE1-S located on the sloped surface SSL1 of the recess BNK-R of the bank layer BNK, a bottom portion AE1-B connected to the bottom portion of the sloped portion AE1-S, and a top portion AE1-T connected to the top portion of the sloped portion AE1-S and located on the top of the bank layer BNK. The inclination angle of the sloped portion AE1-S of the first pixel electrode AE1 may be the same as the inclination angle of the sloped surface SSL1 of the bank layer BNK. For example, the inclination angle of the sloped portion AE1-S may be 20 to 70 degrees. As the inclination angle increases, the viewing angle narrows, and as the inclination angle decreases, luminance may be relatively improved. The first pixel electrode AE1 may have a concave shape.

The first light emitting layer EL1 may be located on a portion of the first pixel electrode AE1 and the first pixel definition layer PDL1. For example, the first light emitting layer EL1 may be located on one surface of the first pixel electrode AE1 and a portion of the first pixel definition layer PDL1 that is exposed by the first opening OP1 formed by the first pixel definition layer PDL1. The first light emitting layer EL1 is formed on the first pixel electrode AE1 and along the first pixel electrode AE1, so it may have an inclined structure.

The first light emitting layer EL1 may be an organic light emitting layer made of an organic material. When the first light emitting layer EL1 corresponds to an organic light emitting layer, the thin film transistor TFT applies a voltage (e.g., a set or predetermined voltage) to the first pixel electrode AE1 of the first light emitting element ED1, and when the common electrode CE of the first light emitting element ED1 receives the common voltage or the cathode voltage, the first light emitting layer EL1 may emit light.

The common electrode CE may be located on the first light emitting layer EL1 in the first light emitting area PA1 and may be located on the first pixel definition layer PDL1 in the first light blocking area BA1.

The second light emitting element ED2 may include a second pixel electrode AE2, a second light emitting layer EL2, and a common electrode CE.

The second pixel electrode AE2 may be arranged to overlap one of the plurality of recesses BNK-R defined by the bank layer BNK. The second pixel electrode AE2 is arranged along the multi-stage sloped surface SSL1 of the bank layer BNK. Accordingly, the second pixel electrode AE2 may have a multi-stage inclined structure. For example, the second pixel electrode AE2 is a structure in which the first sloped portion AE1-S1 having a first inclination θ1 and the second sloped portion AE1-S2 having a second inclination θ2 are stepped. The second sloped portion AE1-S2 extends upward from the first sloped portion AE1-S1. The first pixel electrode AE1 may include a top portion AE1-T connected to the top of the second sloped portion AE1-S2 and located on the top of the bank layer BNK, and a bottom portion AE1-B connected to the bottom of the first sloped portion AE1-S1.

The first sloped portion AE1-S1 has a first inclination θ1, and the second sloped portion AE1-S2 extends from the first sloped portion AE1-S1 and is located on top portion and has a second inclination θ2. The second inclination θ2 may be formed more gently than the first inclination θ1. The second inclination θ2 may be smaller than the first inclination θ1. For example, the first inclination θ1 may be 20° to 30°, and the second inclination θ2 may be 5° to 15°.

The horizontal width d1 of the first sloped portion AE1-S1 may be longer than the horizontal width d2 of the second sloped portion AE1-S2. For example, the horizontal width d1 of the first sloped portion AE1-S1 may be 3 μm to 5 μm, and the horizontal width d2 of the second sloped portion AE1-S2 may be 1 μm to 3 μm.

The second light emitting layer EL2 may be located on a portion of the second pixel electrode AE2 and the second pixel definition layer PDL2. For example, the second light emitting layer EL2 may be located on one side of the second pixel electrode AE2 and a portion of the second pixel definition layer PDL2 that is exposed by the second opening OP2 formed by the second pixel definition layer PDL2. The second light emitting layer EL2 is formed on the second pixel electrode AE2 and along the second pixel electrode AE2, so it may have a multi-stage inclined structure.

The second light emitting layer EL2 may be an organic light emitting layer made of an organic material. When the second light emitting layer EL2 corresponds to an organic light emitting layer, the thin film transistor TFT applies a voltage (e.g., a set or predetermined voltage) to the second pixel electrode AE2 of the second light emitting element ED2, and when the common electrode CE of the second light emitting element ED2 receives the common voltage or the cathode voltage, the second light emitting layer EL2 may emit light.

The common electrode CE may be located on the second light emitting layer EL2 in the second light emitting area PA2 and may be located on the second pixel definition layer PDL2 in the second light blocking area BA2.

The color filters CF1 and CF2 may be located in different light emitting areas EA1 and EA2, respectively. The color filters CF1 and CF2 may include a first color filter CF1 and a second color filter CF2. The color filters CF1 and CF2 and the color pattern CP may include a colorant such as a dye or pigment that absorbs light in a different wavelength band than the light in the specific wavelength band and may be arranged to correspond to the color of the light emitted from the light emitting areas EA1 and EA2.

For example, the first color filter CF1 may be a red color filter arranged to overlap the first light emitting area EA1 and transmit only red first light. The second color filter CF2 may be arranged to overlap the second light emitting area EA2 and may be a green color filter that transmits only the green second light.

As shown in the working example of FIG. 20, by adopting different structures of pixel electrodes in the light emitting areas that emit light of different wavelengths, appropriate compensation according to characteristics depending on the wavelength is possible.

The light emitting area where efficiency of frontal emission of light is desired may adopt a multi-stage structure in which the angle of inclination is sequentially decreased.

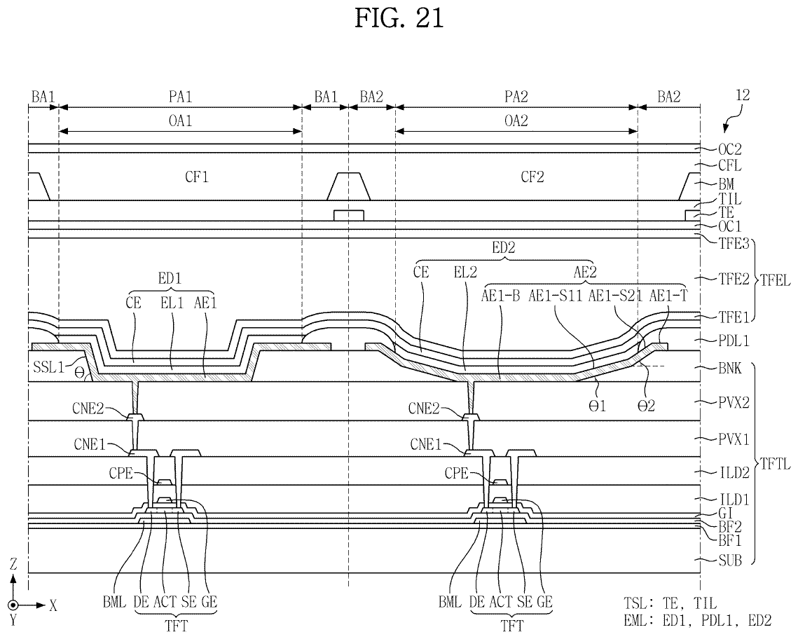

FIG. 21 is a cross-sectional view illustrating a display device including a light emitting area emitting different wavelengths of light, according to some embodiments.

FIG. 21 illustrates a cross-sectional view across the first light emitting area PA1 and the second light emitting area PA2.

The embodiments of FIG. 21 differ from the embodiments of FIG. 20 in that the inclination of the second pixel electrode AE2 of the second light emitting area PA2 increases toward the top. The description will focus on the second light emitting area PA2, which is different from that of FIG. 20.

The cross-sectional structure of the display device 12 will be described with reference to FIG. 21 in addition to FIGS. 11 and 16.

The first light emitting area PA1 and the second light emitting area PA2 may emit light of different wavelengths. For example, the first light emitting area PA1 and the second light emitting area PA2 may each emit red or green light or may each emit blue or green light. However, embodiments according to the present disclosure are not limited thereto.

The first light emitting area PA1 may include the first light emitting element ED1, and the second light emitting area PA2 may include the second light emitting element ED2.

The light emitting elements included in different light emitting areas may have different structures. For example, the first light emitting element ED1 may include a single-layer inclined structure, as described with reference to FIG. 11. As described with reference to FIGS. 16 and 17, the second light emitting element ED2 may include a multi-stage inclined structure in which the inclination gradually increases.

The second light emitting element ED2 may include a second pixel electrode AE2, a second light emitting layer EL2, and a common electrode CE.

The second pixel electrode AE2 may be arranged to overlap one of the plurality of recesses BNK-R defined by the bank layer BNK. The second pixel electrode AE2 is arranged along the multi-stage sloped surface SSL1 of the bank layer BNK. Accordingly, the second pixel electrode AE2 may have a multi-stage inclined structure. For example, the second pixel electrode AE2 is a structure in which the first sloped portion AE1-S1 having a first inclination θ1 and the second sloped portion AE1-S2 having a second inclination θ2 are stepped. The second sloped portion AE1-S2 extends upward from the first sloped portion AE1-S1. The first pixel electrode AE1 may include a top portion AE1-T connected to the top of the second sloped portion AE1-S2 and located on the top of the bank layer BNK, and a bottom portion AE1-B connected to the bottom of the first sloped portion AE1-S1.

The first sloped portion AE1-S11 has a first inclination θ11, and the second sloped portion AE1-S21 extends from the first sloped portion AE1-S11 and is located at the top portion and has a second inclination θ21. The second inclination θ21 may be steeper than the first inclination θ11. For example, the first inclination θ11 may be 20° to 30°, and the second inclination θ2 may be 30° to 60°.

The horizontal width d1 of the first sloped portion AE1-S11 may be longer than the horizontal width d2 of the second sloped portion AE1-S21. For example, the horizontal width d1 of the first sloped portion AE1-S11 may be 3 μm˜5 μm, and the horizontal width d2 of the second sloped portion AE1-S21 may be 1 μm˜3 μm.

The second light emitting layer EL2 may be located on a portion of the second pixel electrode AE2 and the second pixel definition layer PDL2. For example, the second light emitting layer EL2 may be located on one surface of the second pixel electrode AE2 and a portion of the second pixel definition layer PDL2 that is exposed by the second opening OP2 formed by the second pixel definition layer PDL2. The second light emitting layer EL2 is formed on the second pixel electrode AE2 and along the second pixel electrode AE2, so it may have a multi-stage inclined structure.

The second light emitting layer EL2 may be an organic light emitting layer made of an organic material. When the second light emitting layer EL2 corresponds to an organic light emitting layer, the thin film transistor TFT applies a voltage (e.g., a set or predetermined voltage) to the second pixel electrode AE2 of the second light emitting element ED2, and when the common electrode CE of the second light emitting element ED2 receives the common voltage or the cathode voltage, the second light emitting layer EL2 may emit light.

The common electrode CE may be located on the second light emitting layer EL2 in the second light emitting area PA2 and may be located on the second pixel-defining layer PDL2 in in the second light blocking area BA2.

The color filters CF1 and CF2 may be located in different emission areas EA1 and EA2, respectively. The color filters CF1 and CF2 may include a first color filter CF1 and a second color filter CF2. The color filters CF1 and CF2 and the color pattern CP may include a colorant such as a dye or pigment that absorbs light in a different wavelength band than the light in the specific wavelength band and may be arranged to correspond to the color of the light emitted from the light emitting areas EA1 and EA2.

For example, the first color filter CF1 may be a red color filter that is arranged to overlap the first light emitting area EA1 and transmits only the first light of red, or a blue color filter that transmits only the third light of blue. The second color filter CF2 is arranged to overlap the second light emitting area EA2 and may be a green color filter that transmits only the green second light.

The light emitting area in which the luminance ratio deviation for each viewing angle is to be relatively improved may adopt a multi-stage structure in which the angle of inclination is sequentially increased.

According to some embodiments, the light emitted from the first light emitting layer EL1 overlapping the first sloped portion AE1-S1 of the first pixel electrode AE1 to the outside of the display device 10 with an oblique path to the third direction Z may be referred to as a first inclined light LD1 and the light emitted from the first light emitting layer EL1 overlapping the second sloped portion AE1-S2 of the first pixel electrode AE1 to the outside of the display device 10 having an oblique path to the third direction Z may be referred to as a second inclined light LD2. The first inclined light LD1 and the second inclined light LD2 may be emitted from the surface of the display device 10 at various angles to the third direction Z.

When the inclination of the second sloped portion AE1-S2 is greater than the inclination of the first sloped portion AE1-S1, the luminance ratio deviation for each viewing angle may be relatively improved. Because the viewing angle of the second inclined light LD2 is larger than the viewing angle of the first inclined light LD1,

When the inclination of the second sloped portion AE1-S2 is smaller than the inclination of the first sloped portion AE1-S1, white angular dependency (WAD) may be relatively improved, and front light efficiency can be relatively improved. Because the viewing angle of the second inclined light LD2 is smaller than the viewing angle of the first inclined light LD1.

The embodiments disclosed in the disclosure are intended not to limit the technical spirit of embodiments according to the present disclosure but to describe the technical spirit of embodiments according to the present disclosure, and the scope of the technical spirit of embodiments according to the present disclosure is not limited by these embodiments. The protection scope of the disclosure should be interpreted by the following claims, and their equivalents, and it should be interpreted that all technical spirits within the equivalent scope are included in the scope of embodiments according to the present disclosure.

What is claimed is:

1. A display device comprising:
a substrate;
a thin film transistor on the substrate;
a protective layer on the thin film transistor;
a bank layer on the protective layer and having a plurality of recesses;
a plurality of light emitting elements including a pixel electrode, a light emitting layer, and a common electrode corresponding to each of the plurality of recesses on the bank layer; and
a pixel definition layer defining a light emitting area on the bank layer,
wherein a recess from among the recesses has a multi-stage slope, and the pixel electrode includes a first sloped portion having a first inclination along the multi-stage slope of the recess, and a second sloped portion above the first sloped portion and having a second inclination different from the first inclination,
wherein a horizontal width of the first sloped portion is wider than a horizontal width of the second sloped portion.

2. The display device of claim 1, wherein the horizontal width of the first sloped portion is in a range of 3 micrometers (μm) to 5 μm,
wherein the horizontal width of the second sloped portion is in a range of 1 μm to 3 μm.

3. The display device of claim 1, wherein the second inclination is smaller than the first inclination.

4. The display device of claim 3, wherein the first inclination is in a range of 20° to 30°,
wherein the second inclination is in a range of 5° to 15°.

5. The display device of claim 1, wherein the pixel electrode further comprises a bottom portion connected to a bottom of the first sloped portion, and a top portion connected to a top of the second sloped portion and on a top surface of the bank layer.

6. The display device of claim 5, wherein the pixel definition layer partially overlaps the top portion.

7. The display device of claim 1, wherein the light emitting layer overlaps a bottom portion, a first sloped portion, and a second sloped portion of the pixel electrode.

8. The display device of claim 1, wherein the second inclination is greater than the first inclination.

9. The display device of claim 8, wherein the first inclination is in a range of 10° to 30°,
wherein the second inclination is in a range of 30° to 60°.

10. The display device of claim 1, wherein the recess has a multi-stage inclined structure.

11. A display device comprising:
a substrate including a first light emitting area and a second light emitting area;
a thin film transistor on the substrate;
a protective layer on the thin film transistor;
a bank layer on the protective layer and having a first recess and a second recess overlapping the first light emitting area and the second light emitting area, respectively;
a first light emitting element including a first pixel electrode, a first light emitting layer, and a common electrode on the bank layer to correspond to the first recess;
a second light emitting element including a second pixel electrode, a second light emitting layer, and a common electrode on the bank layer to correspond to the second recess; and
a pixel definition layer defining a light emitting area on the bank layer,
wherein the first pixel electrode has a single-layer inclined portion,
wherein the second pixel electrode has a multi-layer inclined portion, and the multi-layered inclined portion includes a first sloped portion having a first inclination, and a second sloped portion above the first sloped portion and having a second inclination different from the first inclination,
wherein a horizontal width of the first sloped portion is wider than a horizontal width of the second sloped portion.

12. The display device of claim 11, wherein the horizontal width of the first sloped portion is in a range of 3 micrometers (μm) to 5 μm,
wherein the horizontal width of the second sloped portion is in a range of 1 μm to 3 μm.

13. The display device of claim 12, wherein the second inclination is smaller than the first inclination.

14. The The display device of claim 11, wherein the first inclination is in a range of 20° to 30°,
wherein the second inclination is in a range of 5° to 15°.

15. The display device of claim 11, wherein the first recess has a single-layer inclined structure,
wherein the second recess has a multi-stage inclined structure.

16. The display device of claim 11, wherein the second inclination is greater than the first inclination.

17. The display device of claim 16, wherein the first inclination is in a range of 10° to 30°,
wherein the second inclination is in a range of 30° to 60°.

18. The display device of claim 11, wherein the second light emitting layer overlaps a bottom portion, a first sloped portion, and a second sloped portion of the second pixel electrode.

19. The display device of claim 11, further comprising: a thin film encapsulation layer on the first light emitting element and the second light emitting element;
a color filter layer on the thin film encapsulation layer;
an overcoat layer and a touch electrode layer between the thin film encapsulation layer and the color filter layer,
wherein the thin film encapsulation layer includes a first inorganic film layer, a second inorganic film layer, and an organic film layer between the first inorganic film layer and the second inorganic film layer.

20. The display device of claim 19, wherein the color filter layer includes a first color filter overlapping the first light emitting area and a second color filter overlapping the second light emitting area,
wherein the first color filter is either a blue color filter configured to transmit blue light or a red color filter configured to transmit red light, and the second color filter is a green color filter configured to transmit green light.
